(19) United States
(12) Patent Application Publication
(10) Pub. No.: US 2024/0321564 A1
(43) Pub. Date: Sep. 26, 2024

(54) INDIRECT PLASMA HEALTH MONITORING

(71) Applicant: Applied Materials, Inc., Santa Clara, CA (US)

(72) Inventors: Tobin Kaufman-Osborn, Arvada, CO (US); MARTIN HILKENE, Gilroy, CA (US)

(21) Appl. No.: 18/124,401

(22) Filed: Mar. 21, 2023

(51) Int. Cl. H01J 37/32

(52) U.S. Cl. CPC H01J 37/32926; H01J 37/32357; H01J 37/3244; H01J 37/32522; H01J 37/32724

(57) ABSTRACT

Embodiments disclosed herein may include a processing tool. In an embodiment, the processing tool includes a chamber, and a remote plasma source (RPS) coupled to the chamber by an adapter. In an embodiment, the processing tool further comprises an RPS match coupled to the RPS, and a first temperature sensor in the chamber. In an embodiment, a second temperature sensor is in the adapter.

### BACKGROUND

### 1) Field

Embodiments relate to the field of semiconductor manufacturing and, in particular, a semiconductor processing chamber with indirect plasma health monitoring.

### 2) Description of Related Art

Semiconductor processing environments in chambers are carefully balanced in order to maintain a steady state. Keeping the environment in a steady state is crucial for maintaining process uniformity of substrates (e.g., wafers) that are processed in the chambers. The desired steady state conditions are dependent on maintaining good chamber health. The chamber health may include parameters such as an accurate power input, functional heat exchanges and other thermal components, no leaks, and the like.

Currently, it is difficult to monitor the processing environment of the chamber to ensure that everything is working as desired. Instead, metrology of the processed substrates is used to determine when the chamber experiences an excursion from the desired steady state condition. This can result in misprocessed substrates, which increases costs and reduces throughput.

### SUMMARY

Embodiments disclosed herein may include a processing tool. In an embodiment, the processing tool includes a chamber, and a remote plasma source (RPS) coupled to the chamber by an adapter. In an embodiment, the processing tool further comprises an RPS match coupled to the RPS, and a first temperature sensor in the chamber. In an embodiment, a second temperature sensor is in the adapter.

Embodiments may also include a method of monitoring a health of a processing tool. In an embodiment, the method comprises generating a training data set for the processing tool, where the training data set comprises at least a first temperature range for a first location within the processing tool and a second temperature range for a second location within the processing tool. In an embodiment, the method may further comprise initiating a plasma process in the plasma chamber, and monitoring a first temperature at the first location and a second temperature at the second location. In an embodiment, the method may further comprise generating an alert when the first temperature is outside the first temperature range and/or the second temperature is outside the second temperature range.

Embodiments disclosed herein may further comprise a processing tool, comprising a chamber, and a remote plasma source (RPS) coupled to the chamber by an adapter. In an embodiment, the processing tool may further comprise an RPS match coupled to the RPS, where the RPS match comprises, one or more sensors including sensors for measuring a stub setting, a forward power setting, a power setpoint and feedback setting, a reflected power and, a tuning match position. In an embodiment, the processing tool may further comprise a mass flow meter (MFM) coupled to the RPS, where the MFM is configured to measure an amount of gas sent to the RPS, a first temperature sensor in the chamber, and a second temperature sensor in the adapter.

### BRIEF DESCRIPTION OF THE DRAWINGS

FIG. 1A is a plan view illustration of a semiconductor processing tool with a remote plasma source (RPS) with indirect process monitoring sensors, in accordance with an embodiment.

FIG. 1B is a plan view illustration of a semiconductor processing tool with an RPS and a plurality of indirect process monitoring sensors, in accordance with an additional embodiment.

FIG. 1C is a cross-sectional illustration of a semiconductor processing tool with an RPS at the top of the tool, in accordance with an embodiment.

FIG. 1D is a plan view illustration of a semiconductor processing tool with an RPS at a side of the tool for a cross-flow setup, in accordance with an embodiment.

FIG. 2 is a process flow diagram of a process for monitoring the chamber health using one or more temperature sensors at various locations within the tool, in accordance with an embodiment.

FIG. 3 is a process flow diagram of a process for monitoring the chamber health using a mass flow meter and plasma match settings, in accordance with an embodiment.

FIG. 4A is a graph of thickness versus drift index for various power settings, in accordance with an embodiment.

FIG. 4B is a graph of the drift index versus RPS power, in accordance with an embodiment.

FIG. 5A is a graph of the drift index versus leak status, in accordance with an embodiment.

FIG. 5B is a graph of thickness versus drift index for leaking and non-leaking chambers, in accordance with an embodiment.

FIG. 6A is a graph of thickness versus drift index that shows first wafer effects, in accordance with an embodiment.

FIG. 6B is a graph of target profile versus drift index that shows first wafer effects, in accordance with an embodiment.

FIG. 7 illustrates a block diagram of an exemplary computer system that may be used in conjunction with a processing tool, in accordance with an embodiment.

### DETAILED DESCRIPTION

Systems described herein include a semiconductor processing chamber with indirect plasma health monitoring. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, semiconductor processing tools are delicate systems that can be easily sent out of specification due to many different component degradations. For example, plasma power needs to be accurately reported, heat exchangers need to work as designed, other thermal systems need to be functioning properly, systems need to be leak free, and many other systems need to be fully functional. However, there is currently not a system that allows for real time monitoring of the chamber health. Accordingly, chamber health is monitored by performing metrology on processed substrates. This is a time consuming process, and can result in high levels of scrap or substrates that need reprocessing.

Accordingly, embodiments disclosed herein include chamber health monitoring systems that indirectly measure the chamber health. In some embodiments, a series of sensors are provided throughout the chamber in order to monitor chamber conditions. In an embodiment, the sensors may be used in conjunction with machine learning (ML) or artificial intelligence (AI) systems in order to monitor the chamber health. Generally, the ML or AI system is trained to have a training data set for a specific chamber. Comparisons between the sensors and the training data set can be used to identify excursions or drift from a particular chamber condition.

In one embodiment, the sensors include temperature sensors. The temperature sensors can detect variations from desired temperature ranges, which can indicate an excursion event. The desired temperature ranges may be provided by the trained ML or AI system. In some embodiments, the temperature sensors may be located throughout the tool. For example, a temperature sensor may be provided in an adapter between a remote plasma source (RPS) and a chamber, and on a reflector within the chamber. Though, other locations may also be used in some embodiments.

In another embodiment, multiple sensors may be configured to provide leak detection indications. For example, a combination of sensors may be used to create a virtual sensor for leak detection. Sensors used may include mass flow rate, pressure, temperature and differential pressure. Additionally, sensor data provided by the remote plasma source may be fed into the virtual sensor algorithm. Sensors data may include power setpoint and feedback, reflected power and, in some RPS types, the tuning match positions may be used-In yet another embodiment, leak detection may be aided with sensors, such as, but not limited to pressure gauges, optical sensors, and the like. When the sensors indicate drift of those settings, an indication that a leak has occurred can be generated.

Generally, embodiments disclosed herein are suitable for use with any semiconductor processing tool. In a more specific embodiment, the semiconductor processing tool includes a RPS. For example, embodiments disclosed herein may include a semiconductor processing tool that is used for rapid thermal processing (RTP), such as an oxidation treatment. In such embodiments, an array of heating lamps may be provided above a substrate. A reflector plate may be provided below the substrate in order to reflect thermal energy back towards the substrate. In an embodiment, an RPS may be coupled to the chamber to provide improved oxidation performance.

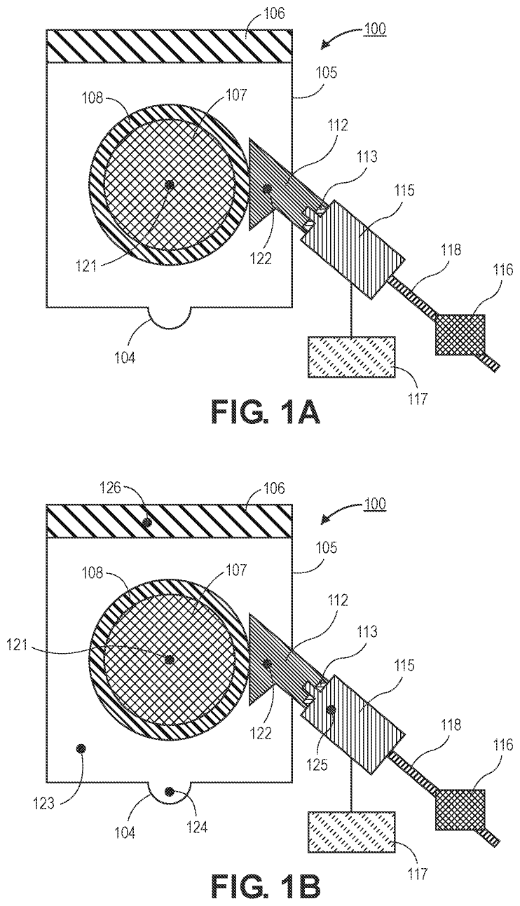

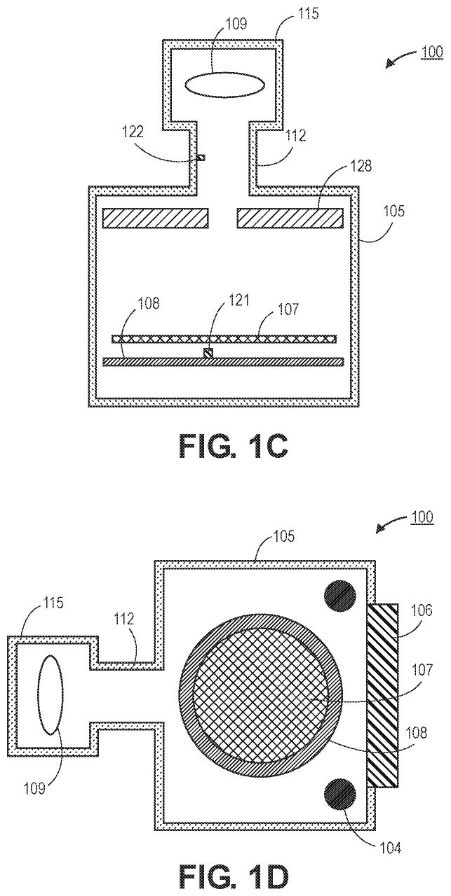

Referring now to FIG. 1A, a plan view illustration of a semiconductor processing tool 100 is shown, in accordance with an embodiment. In an embodiment, the semiconductor processing tool 100 may comprise a chamber 105. The chamber 105 may have any chamber configuration. For example, the chamber 105 may be suitable for low pressure environments or near atmospheric pressure environments. In an embodiment, the chamber 105 may include a support for holding a substrate 107. The substrate 107 may be a semiconductor substrate, such as a silicon wafer or the like. The substrate 107 may have any suitable form factor (e.g., 200 mm, 300 mm, 450 mm, etc.).

In an embodiment, the semiconductor processing tool 100 is a RTP tool. For example, an array of thermal lamps (not shown) may be provided above (i.e., out of the plane of FIG. 1A) the substrate 107. The lamps may be suitable for rapidly increasing the temperature of the substrate 107 in order to enable thermally driven processes, such as thermal oxidation. In an embodiment, a reflector plate 108 may be provided below the substrate 107. The reflector plate 108 may reflect thermal energy back up to the substrate 107.

In an embodiment, the chamber 105 may comprise additional components as well. For example, a slit valve insert (SVI) 106 may be provided along a sidewall of the chamber 105. The SVI 106 may be the opening through which substrate 107 are inserted and retracted from the chamber 105. In an embodiment, the chamber 105 may also include an exhaust 104. The exhaust 104 may be an outlet for removing gasses or other byproducts from the chamber 105. The exhaust 104 may include piping, pumps, and the like.

In an embodiment, an RPS 115 may be provided as part of the semiconductor processing tool. The RPS 115 may generate a plasma outside of the chamber 105, and an adapter 112 may be fluidically coupled between the chamber and the RPS 115. The adapter 112 may be a ceramic lined stainless steel component. For example, the ceramic may include quartz or the like. In an embodiment, the RPS 115 may be controlled (at least in part) by an RPS match 117. It is to be appreciated that components such as a magnetron and generator (not shown) may also be used to control the RPS 115. The RPS match 117 may include settings for forward power, stub settings, and the like. In an embodiment, a mass flow meter (MFM) 116 may be provided along a gas line 118 that feeds the RPS 115. Additional sensors such as pressure sensors (including differential pressure sensors) and optical sensors (not shown) may also be used to monitor performance of the RPS 115.

In an embodiment, the RPS 115 may be coupled to the adapter 112 by a gasket 113, such as an O-ring or the like. The gasket 113 may be a wear component that degrades over use of the semiconductor processing tool 100. For example, the gasket 113 may be a common source of leaks for the semiconductor processing tool 100. Though, it is to be appreciated that other locations may generate leaks as well.

In an embodiment, a plurality of sensors may be provided within the semiconductor processing tool 100. For example, a first sensor 121 may be provided in the chamber 105. More particularly, the first sensor 121 may be configured to detect a temperature of the reflector plate 108. The first sensor 121 may be any suitable sensor type. For example, the first sensor 121 may be a thermocouple or the like. The first sensor 121 may directly contact the reflector plate 108 in some embodiments.

In an embodiment, the plurality of sensors may further comprise a second sensor 122 that is provided on or in the adapter 112. The second sensor 122 may also be a temperature sensor. The second sensor 122 may provide a measure of the temperature of the adapter 112 (either internally or externally).

The plurality of sensors may be used in order to detect chamber drift or excursions of a particular process. In one embodiment, a plurality of sensors may provide temperature readings that are compared with reference temperatures. If the measured temperatures exceed predetermined thresholds around the reference temperatures, then an indication of significant chamber drift or an excursion may be generated. Generally, the reference temperatures and the thresholds are determined through the use of ML or AI applications that are trained on the semiconductor processing tool 100. A more detailed explanation of the ML or AI processes are described in greater detail below.

In another embodiment, the plurality of sensors may provide leak detection monitoring. For example, sensors within the RPS match may measure the stub and forward power settings. Sensors for monitoring the RPS may also include pressure sensors (including differential pressure sensors), optical sensors, and the like. Additionally, the MFM may measure the amount of gas provided to the RPS. When significant changes to any of the sensors are detected (e.g., outside of a predetermined threshold), an alert that a leak is present may be generated. Similar to the temperature sensor embodiment, the predetermined thresholds for leak detection may be generated with ML or AI applications that are trained on the semiconductor processing tool 100.

While temperature sensors and leak detection sensors are disclosed as alternative embodiments, it is to be appreciated that embodiments may include both temperature sensors and leak detection sensors. Additional sensors may be used, such as pressure sensors, differential pressure sensors, and optical sensors as well. Such a combination provides a more robust system for diagnosing the health of the semiconductor processing tool 100.

Referring now to FIG. 1B, a plan view illustration of a semiconductor processing tool 100 is shown, in accordance with an additional embodiment. In an embodiment, the semiconductor processing tool 100 in FIG. 1B may be substantially similar to the semiconductor processing tool 100 in FIG. 1A, with the exception of the plurality of sensors. In an embodiment, the semiconductor processing tool 100 may include additional sensors. For example, a third sensor 123 may be provided within the chamber 105. The third sensor 105 may be a temperature sensor. The third sensor 123 may be used to measure a temperature of a sidewall surface, a bottom surface, or other surface within the chamber 105.

In an embodiment, a fourth sensor 124 may also be used in some embodiments. The fourth sensor 124 may also be a temperature sensor. As shown in FIG. 1B, the fourth sensor 124 may be located within the exhaust 104. The fourth sensor 124 may be positioned at any point within the exhaust 104 system. For example, the fourth sensor 124 may be at the entrance of the exhaust 104, at the pump, or after the pump.

In an embodiment, a fifth sensor 125 may be used as well. The fifth sensor 125 may be a temperature sensor in some embodiments. The fifth sensor 125 may be located within the RPS 115. For example, the fifth sensor 125 may measure a sidewall temperature of the chamber of the RPS 115.

In an embodiment, a sixth sensor 126 may be used as well. The sixth sensor 126 may be a temperature sensor in some embodiments. The sixth sensor 125 may be located within the SVI 106.

While described as temperature sensors, the additional sensor 123-125 may also include other types of sensors. For example, the sensors 123-125 may include pressure sensors, optical sensors, and the like.

As illustrated, a plurality of different sensor locations can be used for excursion detection. The inclusion of more sensors may allow for improved drift detection. That is, some portions of the semiconductor processing tool 100 may drift before other portions of the semiconductor processing tool 100, depending on the mechanism that is causing the drift. For example, if the reflector plate 108 becomes dirty or a redeposition coating is formed over the reflector plate 108, then changes to the temperature of the first sensor 121 may be an initial indicator of drift before other temperatures start to change.

It is to be appreciated that the RPS may be located at various positions relative to the chamber. For example, a top RPS setup may be used in some embodiments. In such an embodiment, the plasma enters the chamber from above. In other embodiments, a cross-flow setup may be used. In such an embodiment, the RPS is located to the side of the chamber, and the plasma flows across the chamber. Examples of such embodiments are shown in FIGS. 1C and 1D. While particular embodiments are shown, it is to be appreciated that any RPS configuration may be used in conjunction with embodiments described herein.

Referring now to FIG. 1C, a cross-sectional illustration of a top RPS 115 setup is shown, in accordance with an embodiment. As shown, the RPS 115 with a plasma 109 is provided above the chamber 105. An adapter 112 may couple the RPS 115 to the chamber 105. In an embodiment, lamps 128 may be provided at the lid of the chamber 105 above the substrate 107 and the reflector plate 108. Sensors 122 and 121 may also be provided in the adapter 112 and on the reflector plate 108, respectively.

Referring now to FIG. 1D, a plan view illustration of a cross-flow embodiment is shown, in accordance with an embodiment. The RPS 115 with the plasma 109 is provided off to a side of the chamber 105. An adapter 112 may couple the RPS 115 to the chamber 105. In an embodiment, the plasma flows across the chamber 105 towards exhaust 104 features. The SVI 106 may be on the opposite side of the chamber 105 from the RPS 115.

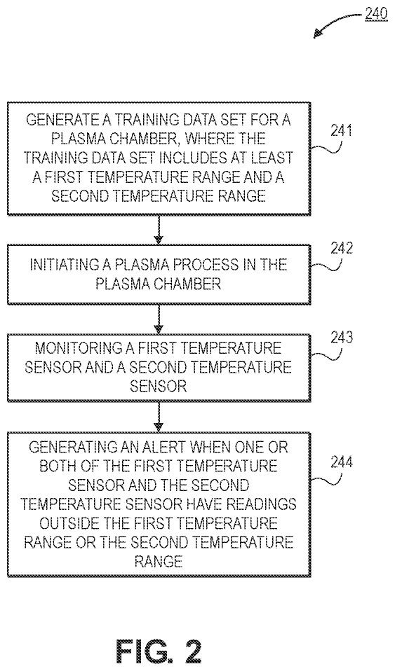

Referring now to FIG. 2, a process flow diagram of a process 240 for monitoring a semiconductor processing tool is shown, in accordance with an embodiment. In an embodiment, the semiconductor processing tool may be similar to one of the semiconductor processing tools described in greater detail above. For example, the semiconductor processing tool may comprise an RTP tool with an RPS.

In an embodiment, process 240 may begin with operation 241, which comprises generating a training data set for a plasma chamber. In an embodiment, the training data set includes at least a first temperature range and a second temperature range. The first temperature range may be an acceptable temperature range in a first location of the semiconductor processing tool, and the second temperature range may be an acceptable temperature range in a second location of the semiconductor processing tool. For example, in the case of a RTP chamber with an RPS, the first location may be a reflector plate, and the second location may be an adapter between the RPS and the chamber. In the case of additional sensors, such as described in FIG. 1B, there may be third ranges, fourth ranges, fifth ranges, etc. at different locations as well. For example, temperature ranges at the exhaust, within the RPS, and within the chamber body may also be used in some embodiments.

The training data set may be used by ML or AI tools in order to set the temperatures ranges. Any ML or AI algorithms that can be used to generate a digital model of the semiconductor processing tool may be used. For example, the training data set may include substrate outcomes (e.g., layer thickness, thickness uniformity, thickness composition, etc.) that can be measured using metrology tools. The substrate outcomes can then be correlated to chamber conditions (e.g., temperatures). The ML or AI algorithms then develop the temperature ranges from the training data that allow for acceptable levels of chamber drift.

The amount of drift may be correlated to a drift index. The drift index may be a value between 0 and 1. When there is no drift, the drift index is at 0, and as drift increases the drift index increases toward 1. In some embodiments, the temperature ranges may correlate to a drift index that is up to approximately 0.4, up to approximately 0.3, or up to approximately 0.2, depending on the robustness of the given process.

In an embodiment, the process 240 may continue with operation 242, which comprises initiating a plasma process in the plasma chamber. In an embodiment, the plasma process may be a plasma oxidation process. Though, it is to be appreciated that embodiments may include any type of plasma based process (e.g., an etch process, a deposition process, or the like). In an embodiment, the plasma process that is initiated in operation 242 is the same process that was mapped to form the training data set in operation 241. In an embodiment, initiating the plasma process may include bringing the plasma chamber up to a steady state condition. This may include processing several substrates in order to get past any first wafer effects that may otherwise indicate an excursion is occurring.

In an embodiment, the process 240 may continue with operation 243, which comprises monitoring a first temperature sensor and a second temperature sensor. In an embodiment, the first temperature sensor is in the first location (e.g., the reflector plate), and the second temperature sensor is in the second location (e.g., the adapter between the RPS and the chamber). While two specific locations are provided in operation 243, it is to be appreciated that other locations (e.g., exhaust, within the RPS, within the SVI, within the chamber, etc.) may also be monitored as well. In an embodiment, the first temperature sensor and the second temperature sensor may be any suitable temperature sensor architecture. In one embodiment, the first temperature sensor and the second temperature sensors are contact sensors that require direct contact with the surface that is being monitored. For example, the temperature sensors may include thermocouples. Though, contactless temperature sensing options (e.g., pyrometers) may also be used in some embodiments.

In an embodiment, the process 240 may continue with operation 244, which comprises generating an alert when one or both of the first temperature sensor and the second temperature sensor have readings outside the first temperature range or the second temperature range. When a temperature reading is outside of the predetermined range, it can be presumed that the semiconductor processing tool has drifted beyond a given tolerance. As such, an alert may be provided that indicates further inspection, maintenance, or the like is needed for the semiconductor processing tool.

Exceeding the temperature range may be indication that one or more of the components of the semiconductor processing tool are damaged, dirty, worn, or otherwise not functioning properly. For example, if the temperature readings drop, then the power supplied to the plasma may be decreasing. In one instance the power supply may be miscalibrated. That is, the power supply may indicate that 2,500 W are being supplied, while only 2,300 W are really being supplied. As such, the settings of the semiconductor processing tool may not indicate there is a problem, but the temperature sensors will detect the chamber drift. Since the sensors do not directly detect a change in the component that is drifting (e.g., the power source in this case), the monitoring may be referred to as being indirect.

In the embodiment described with respect to FIG. 2, a set of two sensors are used. However, it is to be appreciated that embodiments may include a single sensor or more than two sensors. The multitude of sensors may be distributed throughout the semiconductor processing tool. For example, temperature sensors may be included in locations, such as those described above with respect to FIG. 1B.

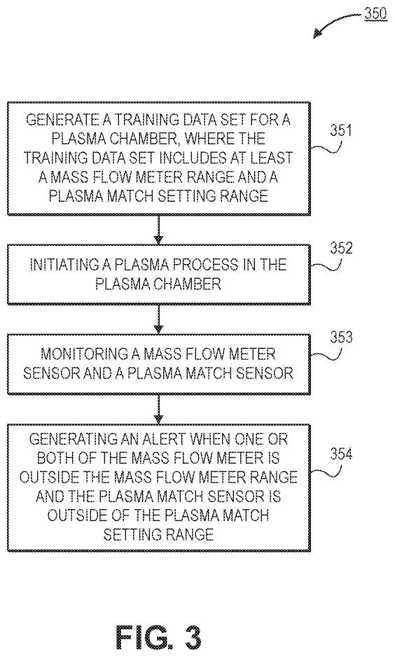

Referring now to FIG. 3, a process flow diagraph of a process 350 for monitoring a semiconductor processing tool is shown, in accordance with an additional embodiment. In an embodiment, the semiconductor processing tool may be similar to one of the semiconductor processing tools described in greater detail above. For example, the semiconductor processing tool may comprise an RTP tool with an RPS.

In an embodiment, the process 350 may begin with operation 351, which comprises generating a training data set for a plasma chamber. In an embodiment, the training data set may include a MFM range, a plasma match setting range, pressure ranges, and optical sensor ranges. In an embodiment, the training data set may be used by ML or AI in order to develop the acceptable ranges. The ML or AI processes used to form the ranges may be similar to the ML and AI processes described in greater detail above with respect to FIG. 2.

In an embodiment, the process 350 may continue with operation 352, which comprises initiating a plasma process in the plasma chamber. In an embodiment, the plasma process may be a plasma oxidation process. Though, it is to be appreciated that embodiments may include any type of plasma based process (e.g., an etch process, a deposition process, or the like). In an embodiment, the plasma process that is initiated in operation 352 is the same process that was mapped to form the training data set in operation 351. In an embodiment, initiating the plasma process may include bringing the plasma chamber up to a steady state condition. This may include processing several substrates in order to get past any first wafer effects that may otherwise indicate an excursion is occurring.

In an embodiment, the process 350 may continue with operation 353, which comprises monitoring a MFM sensor and a plasma match sensor. In an embodiment, the MFM sensor monitors the amount of gas that is flown into the RPS chamber. The plasma match sensor may monitor settings of the plasma match. For example, stub settings, forward power settings, power setpoint and feedback, reflected power and, in some RPS types, the tuning match positions may be monitored by the plasma match sensor.

In an embodiment, the process 350 may continue with operation 354, which comprises generating an alert when one or both of the MFM sensor is outside of the MFM range and the plasma match sensor is outside the plasma match setting range. When a temperature reading is outside of the predetermined range, it can be presumed that the semiconductor processing tool has drifted beyond a given tolerance. As such, an alert may be provided that indicates further inspection, maintenance, or the like is needed for the semiconductor processing tool.

Exceeding one or both of the ranges may be an indication that there is leak in the system. For example, the gasket or O-ring between the RPS chamber and the adapter may be worn or defective and result in a leak. Due to the leak, more gas enters the RPS chamber, and the increased gas flow will be detected by the MFM sensor. Similarly, the RPS match sensor may detect changes to the system that need to be made in order to mitigate reflected power due to the leak. Instead of relying on sensors that are in closed loop process control, indirect methods, such as those described herein may be used. Since the sensors do not directly detect a change in the component that is drifting (e.g., the leak in this case), the monitoring may be referred to as being indirect.

In the embodiment described with respect to FIG. 3, both a MFM sensor and an RPS match sensor are used in conjunction with each other in order to improve sensitivity. However, it is to be appreciated that either a MFM sensor or an RPS match sensor may be used in isolation to detect leaks in some embodiments.

Further, the embodiments described with respect to FIG. 2 may be used in combination with the embodiments described with respect to FIG. 3. For example, both temperature sensing as an indirect measure for chamber health and indirect leak detection may be implemented at the same time or on the same plasma process within a semiconductor processing tool.

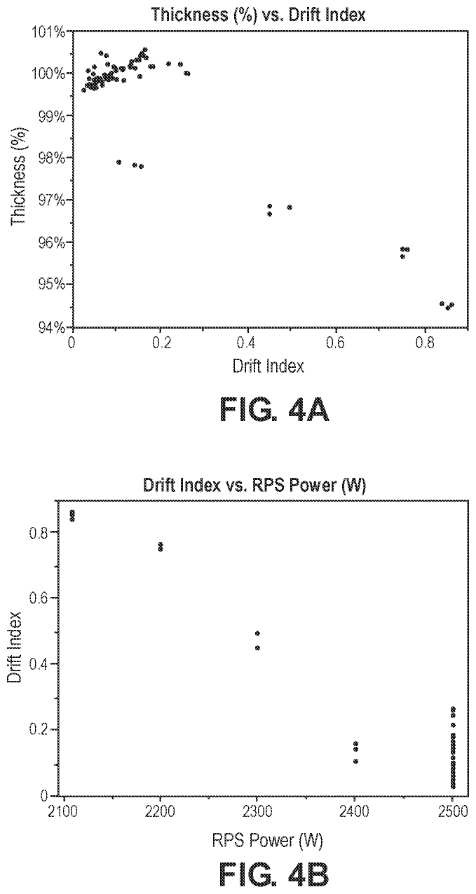

Referring now to FIGS. 4A-6B, a series of graphs that illustrate different conditions within a semiconductor processing tool and how those conditions relate to chamber health or leak status is shown, in accordance with an embodiment.

Referring now to FIG. 4A, a graph of thickness (with 100% being the target thickness) of a layer with respect to a drift index value is shown, in accordance with an embodiment. The drift index may be generated using ML or AI algorithms. For example, a training data set may be run through ML or AI algorithms in order to come up with the drift index. In an embodiment, the drift index may be associated with one or more different temperature readings throughout the semiconductor processing tool. As shown, the majority of data points with drift indices that are less than 0.4 are grouped around 100% of the target thickness. As such, an alert may be triggered when processing conditions lead to a drift index around or greater than 0.4.

Referring now to FIG. 4B, a graph of drift index versus RPS power is shown, in accordance with an embodiment. The graph in FIG. 4B is used to show how different power settings can be detected. The target power is 2,500 W. As shown, all of the data points at 2,500 W are below 0.4 on the drift index. However, as power decreases, especially starting at 2,300 W, the drift index begins to raise above 0.4. What this graph shows, is that even when the output power is showing as being 2,500 W, if the drift index is indicating a value over 0.4, then the true power that is being applied to the system is less than 2,500 W. For example, the power supply may be worn, improperly calibrated, or otherwise damaged. As such, an alert may be generated in order to indicate that further inspection of the system may be needed.

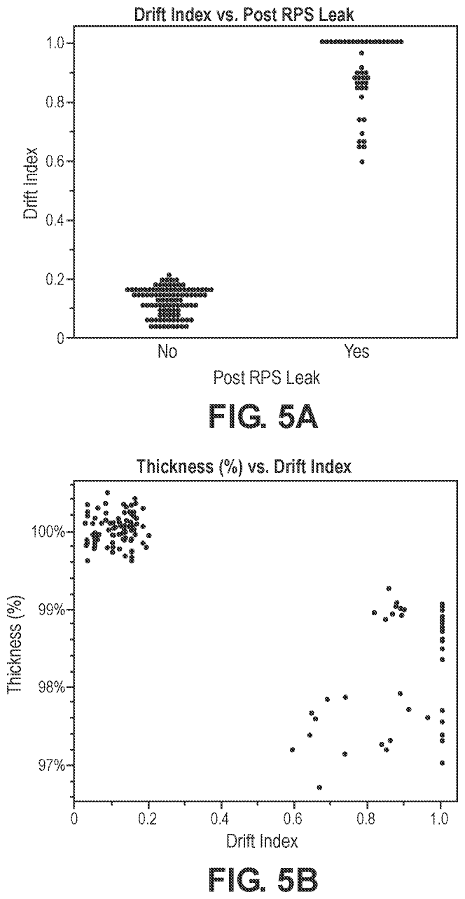

Referring now to FIG. 5A, a graph of drift index versus leak status is shown, in accordance with an embodiment. The illustrated data was prepared by measuring drift index for a series of points when there was no leak, and measuring drift index for a series of points where there was a confirmed leak. As shown, the leak status is clearly indicated by the drift index. The leak free data points have drift indices that are around 0.2 or lower, and the leaking data points have drift indices that around 0.6 or greater.

The difference in drift index is also demonstrated in FIG. 5B, which shows the thickness percentage versus the drift index. The grouping of data points in the top left are the leak free data points. As shown, the leak free points have low drift indices and are grouped around the target thickness (i.e., 100%). In contrast the leaking data points (bottom right) are widely spread and generally have drift indices that are around 0.6 or higher.

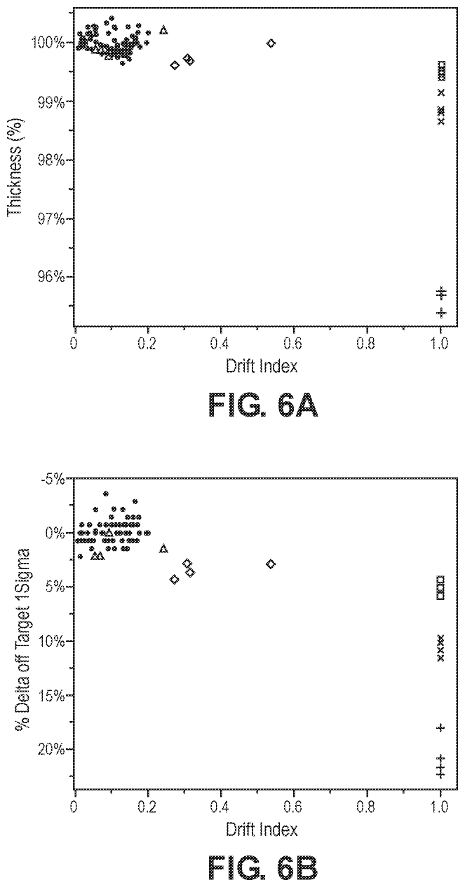

Drift indices may also be used to detect first wafer effects. As the name implies, first wafer effects occur during the processing of the first several wafers. During this time, the semiconductor processing tool may be in a non-steady state mode. For example, the chamber may be warming up. Examples of such warmup routines are shown in FIGS. 6A and 6B. In FIGS. 6A and 6B, the crosses are the first wafers, the X's are the second wafers, the squares are the third wafers, the diamonds are the fourth wafers, and the triangles are the fifth wafers. The solid circles are the wafers processed once a steady state is reached. As shown in both FIG. 6A and FIG. 6B, the first wafers have high drift indices (e.g., around 1), and the drift indices trend toward around 0.2 or below (with 100% target thickness in FIG. 6A or 0% delta in FIG. 6B) after the first few wafers.

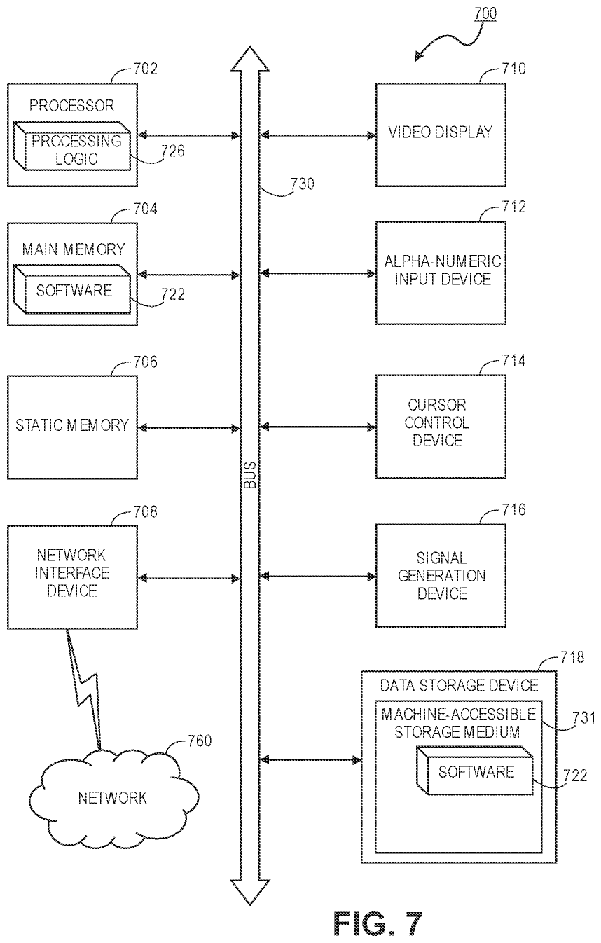

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 760 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A processing tool, comprising:
a chamber;
a remote plasma source (RPS) coupled to the chamber by an adapter;
an RPS match coupled to the RPS;
a first temperature sensor in the chamber; and
a second temperature sensor in the adapter.

2. The processing tool of claim 1, wherein the processing tool is a rapid thermal processing (RTP) tool.

3. The processing tool of claim 2, wherein the chamber comprises a reflector plate, and wherein the first temperature sensor is configured to measure a temperature of the reflector plate.

4. The processing tool of claim 1, wherein the second temperature sensors provides an internal temperature measurement of the adapter or an external temperature measurement of the adapter.

5. The processing tool of claim 1, wherein the adapter is a quartz lined stainless steel adapter.

6. The processing tool of claim 1, further comprising:
a match sensor for the RPS match, wherein the match sensor detects one more of a stub setting, a forward power, a power setpoint and feedback, a reflected power and, a tuning match position.

7. The processing tool of claim 6, further comprising:
a mass flow meter for detecting the mass of gas flown into the RPS.

8. The processing tool of claim 1, further comprising:
a third temperature sensor in an exhaust of the chamber.

9. The processing tool of claim 1, further comprising:
a third temperature sensor in the RPS.

10. The processing tool of claim 1, wherein the first sensor and the second sensor are inputs to a chamber health monitoring algorithm.

11. A method of monitoring a health of a processing tool, comprising:
generating a training data set for the processing tool, wherein the training data set comprises at least a first temperature range for a first location within the processing tool and a second temperature range for a second location within the processing tool;
initiating a plasma process in the plasma chamber;
monitoring a first temperature at the first location and a second temperature at the second location; and
generating an alert when the first temperature is outside the first temperature range and/or the second temperature is outside the second temperature range.

12. The method of claim 11, wherein generating the training data set uses machine learning or artificial intelligence.

13. The method of claim 11, wherein the processing tool is a rapid thermal processing (RTP) tool with a remote plasma source (RPS).

14. The method of claim 13, wherein the first location is a reflector plate within a chamber of the processing tool, and wherein the second location is within an adapter between the RPS and the chamber of the processing tool.

15. The method of claim 13, further comprising:
monitoring for leaks within the processing tool.

16. The method of claim 15, wherein the leak monitoring comprises:
comparing an amount of gas fed to the RPS with a predetermined range of gas flows; and
comparing one or more settings of an RPS match with a predetermined range of RPS match settings.

17. A processing tool, comprising:
a chamber;
a remote plasma source (RPS) coupled to the chamber by an adapter;
an RPS match coupled to the RPS, wherein the RPS match comprises:
one or more sensors including sensors for measuring a stub setting, a forward power setting, a power setpoint and feedback setting, a reflected power and, a tuning match position;
a mass flow meter (MFM) coupled to the RPS, wherein the MFM is configured to measure an amount of gas sent to the RPS;
a first temperature sensor in the chamber; and
a second temperature sensor in the adapter.

18. The processing tool of claim 17, wherein the one or more sensors, the MFM, the first temperature sensor, and the second temperature sensor are configured to provide data that is used by a processor to determine chamber health.

19. The processing tool of claim 18, wherein the processor generates a drift index.

20. The processing tool of claim 19, wherein an alert is generated when the drift index is at or above 0.4 on a scale from 0.0 to 1.0.
